(19) United States
(12) Patent Application Publication
(10) Pub. No.: US 2023/0276845 A1
(43) Pub. Date: Sep. 7, 2023

(54) Aerosol Generation Device with a Nested and Flexible PCB

(71) Applicant: JT INTERNATIONAL S.A., Genève (CH)

(72) Inventors: Kyle Adair, Lisburn (GB); Peter Loveday, Epsom (GB); Olayiwola Olamiposi Popoola, Walton-on-Thames (GB)

(73) Assignee: JT International SA, Geneva (CH)

(21) Appl. No.: 18/019,989

(22) PCT Filed: Jun. 22, 2021
(86) PCT No.: PCT/EP2021/066967

§ 371 Date: Feb. 6, 2023

(30) Foreign Application Priority Data
Aug. 10, 2020 (EP) 20190239.2

(51) Int. Cl. A24F 40/40; H05K 1/14

(52) U.S. Cl. CPC A24F 40/40; H05K 1/147

(57) ABSTRACT

An aerosol generation device with a flexible PCB improves the efficient use of interior space inside the aerosol generation device. An aerosol generation device includes a first rigid printed circuit board (PCB) arranged in a first plane, and a first flexible printed circuit (FPC). The first rigid PCB is attached to a first portion of the first FPC, the first FPC having a first portion of the first FPC is arranged in a second plane that is substantially parallel to and different from the first plane, and a second portion of the first FPC connects the first portion of the first FPC to the first rigid PCB.

### FIELD OF THE INVENTION

The invention relates to an aerosol generation device with a flexible PCB. In particular, the invention relates to an aerosol generation device with a flexible PCB that improves the efficient use of interior space inside the aerosol generation device.

### TECHNICAL BACKGROUND

Aerosol generation devices commonly found on the market nowadays are provided with an increasing number of electronic and/or electrical components for controlling various aspects of the operation of the aerosol generation devices. Such components may comprise a wide range of sensors for measuring ambient operation conditions such as air temperature or humidity, or inhalation characteristics of a user, and may further comprise memory components, processing components, and a range of interfaces for determining, detecting, and controlling various parameters of the operation of an aerosol generation device. Such parameters include the type of a consumable used with the aerosol generation device, heating parameters, and such interfaces include wireless as well as wired interfaces for interfacing or authenticating a consumable.

At the same time, there is a customer demand for improved transportability, usability and aesthetics of aerosol generation devices. As a result, aerosol generation devices are becoming more mobile and more compact, leading to increased spatial constraints inside aerosol generation devices for accommodating and accounting for an increasing number of electronic and/or electrical components. As an additional constraint, some electronic and/or electrical components need to be specifically arranged or positioned in an aerosol generation device. For example, an aerosol generation means that generates an aerosol for inhalation by a user would commonly have to be located at or towards one end of an aerosol generation device, while a charging port and a respective power supply would commonly have to be located at the opposite end of an aerosol generation device.

Typically, electronic and/or electrical components inside an aerosol generation device are connected to each other by being attached, mounted, or otherwise connected to rigid printed circuit boards (PCB) that also find use in virtually all but the simplest electronic products.

To meet customer demands and account for the above-mentioned constraints, a more efficient use of space inside aerosol generation devices is required. Some configurations utilize a plurality of rigid PCBs arranged inside an aerosol generation device at different positions and/or orientations. While these configurations allow for a more effective use of the interior space inside an aerosol generation device, electric wiring and connections between different rigid PCBs require careful and deliberate planning and arrangement of electronic and/or electrical components that needs to be individually adapted to different interior spaces. Therefore, an arrangement of rigid PCBs and electronic and/or electrical components designed for a specific aerosol generation device cannot be readily and easily adapted for another aerosol generation device. This increases manufacturing complexity and expenses.

Other configurations utilize flexi-rigid PCBs. While the use of flexi-rigid PCBs addresses issues involved in providing connections and wirings between different rigid PCBs, most configurations focus on providing connections between rigid PCBs arranged at specific positions inside an aerosol generation, but do not contribute to a more efficient use of the interior space inside an aerosol generation device.

Therefore, there is a need for an aerosol generation device that is provided with circuitry that can be easily adapted for use in different aerosol generation devices and that provides a more efficient use of the interior space of the aerosol generation device.

### SUMMARY OF THE INVENTION

Some, or all of the above objectives are achieved by the invention as defined by the features of the independent claims. Preferred embodiments of the invention are defined by the features of the dependent claims.

A 1^{st} aspect of the invention is an aerosol generation device that comprises a first rigid printed circuit board (PCB) arranged in a first plane, and a first flexible printed circuit (FPC). The first rigid PCB is attached to a first portion of the first FPC, the first FPC comprising a first portion of the first FPC is arranged in a second plane that is substantially parallel to and different from the first plane, and a second portion of the first FPC connects the first portion of the first FPC to the first rigid PCB.

The first rigid PCB is advantageous because it provides a mechanically stable support for electronic and/or electrical components. Furthermore, the first FPC is capable of adapting and conforming to a variety of differently shaped interior spaces and allows the first rigid PCB and the first FPC to be employed in a variety of interior spaces without requiring modification. Additionally, having a portion of the first FPC parallel to the first rigid PCB makes use of the interior space in the direction perpendicular to the first rigid PCB. It also increases the surface area that can accommodate electronic and/or electrical components without the need to increase the size of the first rigid PCB, and further electronic and/or electrical components can be accommodated on the second portion of the first FPC as well. This provides a more efficient use of the interior space of the aerosol generation device and hence allows more functionalities to be provided within the interior space, or it allows the same functionality to be provided in a more compact device with a smaller interior space.

According to a 2^{nd} aspect, in the first aspect, the aerosol generation device comprises a second FPC, wherein the first rigid PCB is attached to a portion of the second FPC, the second FPC comprising, a first portion of the second FPC is arranged in a third plane that is substantially parallel to and different from the first plane and the second plane, and a second portion of the second FPC connects the first portion of the second FPC portion to the first rigid PCB.

The 2^{nd} aspect is advantageous because the second FPC is capable of adapting and conforming to a variety of differently shaped interior spaces and allows the first rigid PCB, the first FPC and the second FPC to be employed in a variety of interior spaces without requiring modification. Additionally, having a portion of the second FPC parallel to the first rigid PCB makes use of the interior space in the direction perpendicular to the first rigid PCB. It also increases the surface area that can accommodate electronic and/or electrical components without the need to increase the size of the first rigid PCB, and further electronic and/or electrical components can be accommodated on the second portion of the second FPC as well. This provides a more efficient use of the interior space of the aerosol generation device and hence allows more functionalities to be provided within the interior space, or it allows the same functionality to be provided in a more compact device with a smaller interior space.

According to a 3^{rd} aspect, in the preceding aspect, the second plane faces a first surface of the first rigid PCB and the third plane faces a second surface of the first rigid PCB that is opposite the first surface of the first rigid PCB.

Having the first portion of the first flexible FPC and the first portion of the second FPC on opposite sides of the first rigid PCB allows the first FPC and the second FPC to adapt and conform to a variety of differently shaped interior spaces and makes use of the interior space in both directions perpendicular to the first plane of the first rigid PCB. This provides a more efficient use of the interior space and allows the aerosol generation device to be provided with more functionalities or to be more compact.

According to a 4^{th} aspect, in the preceding aspect, at least part of the first portion of the first FPC faces the first surface of the first rigid PCB.

According to a 5^{th} aspect, in any one of the 3^{rd} or 4^{th} aspects, at least part of the first portion of the second FPC faces the second surface of the first rigid PCB.

The 4^{th} and 5^{th} aspects are advantageous because they respectively allow the first portion of the first FPC and/or the first portion of the second FPC to improve the use of interior space in an extension direction of the first rigid PCB. This provides a more efficient use of the interior space of the aerosol generation device.

According to a 6^{th} aspect, in any one of the 2^{nd} to 5^{th} aspects, the distance between the first plane and the second plane is different from the distance between the third plane and the first plane.

The 6^{th} aspect is advantageous because it allows the first FPC and the second FPC to adapt to different symmetries of the interior space of the aerosol generation device and provides a more efficient use of the interior space of the aerosol generation device.

According to a 7^{th} aspect, in any one of the preceding aspects, the first rigid PCB, the first portion of the first FPC, and the second portion of the first FPC form a first curved or bent shape in a transversal plane of the aerosol generation device.

According to an 8^{th} aspect, in any one of 2^{nd} to 7^{th} aspects, the first rigid PCB, the first portion of the second FPC, and the second portion of the second FPC form a second curved or bent shape in a transversal plane of the aerosol generation device.

The 7^{th} and 8^{th} aspects are advantageous because they respectively allow electronic and other components of the aerosol generation device to be arranged between the first rigid PCB and the first FPC, thus making more efficient use of the interior space.

According to a 9^{th} aspect, in the 7^{th} and 8^{th} aspects, the first curved or bent shape and the second curved or bent shape are curved or bent in the same direction.

According to a 10^{th} aspect, in the 7^{th} and 8^{th} aspects, the first curved or bent shape and the second curved or bent shape are curved or bent in opposite directions.

The 9^{th} and 10^{th} aspects are advantageous because they respectively allow the first FPC and the second FPC to account for different symmetries of the aerosol device and its components. This provides a more efficient use of the interior space of the aerosol generation device.

According to a 11^{th} aspect, in the 9^{th} aspect, the first curved or bent shape and the second curved or bent shape together form a substantially “E”-letter shaped shape in a transversal plane of the aerosol generation device.

According to a 12^{th} aspect, in the 10^{th} aspect, the first curved or bent shape and the second curved or bent shape together form a substantially “S”-letter shaped shape in a transversal plane of the aerosol generation device.

The 11^{th} and 12^{th} aspects are advantageous because they respectively limit the extensions of the first FPC and the second FPC to substantially the extension of the first rigid PCB, thereby increasing the surface area available for electronic and/or electrical components without substantially increasing the footprint of the first rigid PCB, the first FPC and the second FPC. This provides a more efficient use of the interior space of the aerosol generation device.

According to a 13^{th} aspect, in any one of the preceding aspects, the aerosol generation device has or comprises an elongated shape that is elongated in the direction of a longitudinal axis of the aerosol generation device.

According to a 14^{th} aspect, in any one of 2^{nd} to 12^{th} aspects, the first rigid PCB has or comprises an elongated shape, and at least a portion of the first FPC and the second FPC extends in a direction that is parallel to the longitudinal axis of the first rigid PCB.

The 13^{th} and 14^{th} aspects are advantageous because they allow the first FPC and the second FPC to optimally conform to an interior space of the aerosol generation device that is elongated, thus providing a more efficient use of the interior space of the aerosol generation device.

According to a 15^{th} aspect, in the 12^{th} and the preceding aspect, the longitudinal axis of the first rigid PCB and the longitudinal axis of the aerosol generation device are substantially parallel.

The 15^{th} aspect is advantageous because it allows the first rigid PCB and the first and/or second FPC to optimally conform to the interior space of the aerosol generation device in the longitudinal direction of the aerosol generation device, thus providing a more efficient use of the interior space of the aerosol generation device.

According to a 16^{th} aspect, in any one of the 13^{th} or 14^{th} aspects, the aerosol generation device comprises a second rigid PCB that is connected to a third portion of the first FPC, or a third portion of the second FPC, or a third FPC of which a portion is attached to the first rigid PCB, wherein the second rigid PCB is arranged in a plane that is parallel to a transverse plane of the first rigid PCB.

The 16^{th} aspect is advantageous because it provides a second mechanically stable support for electronic and/or electrical components.

According to a 17^{th} aspect, in any one of the preceding aspects and the 2^{nd} aspect, the first FPC and the second FPC are formed by a single, integrally formed FPC.

According to a 18^{th} aspect, in any one of the preceding aspects and the 2^{nd} and 16th aspects, the first FPC and the second FPC and the third FPC are formed by a single, integrally formed FPC.

The 17^{th} and the 18^{th} aspects are advantageous because having a single, integrally formed FPC eliminates the need for connectors for connecting the first FPC and/or the second FPC and/or the third FPC to the first rigid PCB and/or the second rigid PCB, thus further decreasing the manufacturing complexity. Additionally, installation of the first rigid PCB and the single FPC into an aerosol generation device is simplified as the single FPC can be inserted and brought into a desired shape without the need for connecting parts. This providing a more efficient use of the interior space of the aerosol generation device and decreases manufacturing complexities.

According to a 19^{th} aspect, in any one of the preceding aspects, the aerosol generation device comprises an aerosol generation means for receiving and/or interfacing with a consumable comprising an aerosol generation substrate for generating an aerosol from the aerosol generation substrate.

The 19^{th} aspect is advantageous because it allows the aerosol generation device to operate with different types of consumables.

According to a 10^{th} aspect, in the preceding aspect, the aerosol generation means is provided substantially at a first end of the aerosol generation device.

The 10^{th} aspect is advantageous since consumables such as a cartomizer, a tobacco stick, or an e-liquid reservoir are typically inserted, attached, or otherwise interfaced with the aerosol generation device at an end of the aerosol generation device.

According to a 21^{st} aspect, in the 16^{th} aspect and the preceding aspect, the aerosol generation means is connected to the second rigid PCB.

The 21^{st} aspect is advantageous because it provides a stable mechanical support to the aerosol generation means that is subject to repeated wear and tear due to connecting/disconnecting or insertion/removal of a consumable by a user. This increases the reliability and durability of the aerosol generation means.

According to a 22^{nd} aspect, in any one of the 19^{th} to 21^{st} aspects, the aerosol generation means comprises a heating chamber for receiving a consumable and a heating unit for heating the heating chamber, or circuitry for interfacing with and controlling the operation of a cartomizer.

The 22^{nd} aspect is advantageous because it allows the aerosol generation device to operate with a cartomizer, or a cartridge that contains an aerosol generation substrate.

According to a 23^{rd} aspect, in any one of the preceding aspects, the aerosol generation device comprises a power supply.

According to a 24^{th} aspect, in the preceding aspect, the power supply is a rechargeable power supply and wherein the aerosol generation device comprises a charging interface for charging the rechargeable power supply.

The 24^{th} aspect is advantageous because a rechargeable power supply does not need to be replaced, and the aerosol generation device does not to be opened for exchanging the power supply.

According to a 25^{th} aspect, in any one of 10^{th} or 22^{nd} aspect and the preceding aspect, the charging interface is provided at a second end of the aerosol generation device opposite the first end of the aerosol generation device.

The 25^{th} aspect is advantageous because the aerosol generation means is typically provided at a first end of the aerosol generation device. Therefore, providing the charging interface at the opposite end allows the aerosol generation device to remain compact in size.

According to a 26^{th} aspect, in the preceding aspect, the charging interface is connected to the first rigid PCB.

The 26^{th} aspect is advantageous because it provides a stable mechanical support for the charging interface that is subject to repeated wear and tear due to connecting/disconnecting of a charging means by a user. This increases the reliability and durability of the charging interface.

According to a 27^{th} aspect, in any one of 23^{rd} to 26^{th} aspects, at least a portion of the first FPC wraps around at least a portion of the power supply and, in a transversal plane of the aerosol generation device, at least a portion or all of the of the power supply is arranged between the first portion of the first FPC and the first rigid PCB.

According to a 28^{th} aspect, in the preceding aspect and the 2^{nd} aspect, at least a portion of the second FPC wraps around at least a portion of the power supply and, in a transversal plane of the aerosol generation device, at least a portion or all of the of the power supply is arranged between the first portion of the first FPC and the first portion of the second FPC.

The 27^{th} and 28^{th} aspects are advantageous because they respectively allow the space around a power supply to be utilized for accommodating electronic and/or electrical components of the aerosol generation device that would otherwise remain unused. This provides a more efficient use of the interior space of the aerosol generation device.

According to a 29^{th} aspect, in any of the preceding aspects and the 15^{th} aspect, the extension of at least a portion of the first FPC in the longitudinal direction of the aerosol generation device is larger than 50%, preferably larger than 60%, more preferably larger than 70%, even more preferably larger than 80%, most preferably larger than 90% of the longitudinal extension of the aerosol generation device 100.

According to a 30^{th} aspect, in any of the 2^{nd} to 28^{th} aspects and the 2^{nd} and 15^{th} aspects, the extension of at least a portion of the second FPC in the longitudinal direction of the aerosol generation device is larger than 50%, preferably larger than 60%, more preferably larger than 70%, even more preferably larger than 80%, most preferably larger than 90% of the longitudinal extension of the aerosol generation device 100.

The 29^{th} and 30^{th} aspects are advantageous because by having the first FPC 210 or the second FPC 220 extend along as much of the length of the aerosol generation as possible provides a more efficient use of the interior space for accommodating electronic or electrical components.

According to a 31^{st} aspect, in any one of the preceding aspects and the 15^{th} and 19th aspects, at least 10%, preferably more than 20%, more preferably more than 30%, even more preferably more than 40%, most preferably more than 50% of the extension of a portion of the first FPC in the longitudinal direction of the aerosol generation device extends along at least a portion the heating chamber or cartomizer when received by the aerosol generation device (100).

According to a 32^{nd} aspect, in any one of the preceding claims and the 2nd, 15^{th} and 19th aspects, at least 10%, preferably more than 20%, more preferably more than 30%, even more preferably more than 40%, most preferably more than 50% of the extension of a portion of the second FPC in the longitudinal direction of the aerosol generation device extends along at least a portion the heating chamber or cartomizer when received by the aerosol generation device (100).

The 31^{st} and 32^{nd} aspects are advantageous because by having the first FPC 210 or the second FPC 220 extend along a portion of the heating chamber or cartomizer allows electronic or electrical components to be accommodated at positions in the interior space of the aerosol generation device that would otherwise remain unused. This provides a more efficient use of the interior space of the aerosol generation device.

According to a 33^{rd} aspect, in any one of the preceding aspects and the 15^{th} and 19th aspects, wherein the distance in the longitudinal direction of the aerosol generation device between the heating chamber or the cartomizer when received by the aerosol generation device, and the edge of the first rigid PCB furthest away from the heating chamber or the cartomizer is less than 90%, more preferably less than 80%, even more preferably less than 70%, even more preferably less than 60%, most preferably less than 50% of extension of the first FPC in the longitudinal direction of the aerosol generation device.

According to a 34^{th} aspect, in any one of the preceding aspects and the 2nd, 15^{th} and 19th aspects, the distance in the longitudinal direction of the aerosol generation device between the heating chamber or the cartomizer when received by the aerosol generation device, and the edge of the first rigid PCB furthest away from the heating chamber or the cartomizer is less than 90%, more preferably less than 80%, even more preferably less than 70%, even more preferably less than 60%, most preferably less than 50% of extension of the second FPC in the longitudinal direction of the aerosol generation device.

The 33^{rd} and 34^{th} aspects are advantageous because by reducing the distance between the heating chamber or cartomizer and the first rigid PCB, the cavity typically formed in between is reduced, and the compactness of the aerosol generation device can be increased.

According to a 35^{th} aspect, in any one of the preceding aspects, less than 40%, preferably less than 30%, even more preferably less than 20%, most preferably less than 10% of the interior volume of the aerosol generation device that is defined by a housing of the aerosol generation device as the outer boundary of the interior volume is unoccupied and can be filled with air.

The 35^{th} aspect is advantageous because it provides a more efficient use of the interior space as any unused space, i.e. space that is not occupied by any functional or structural component of the aerosol generation device and that can be filled with air, is reduced. Furthermore, minimizing the amount of air inside the aerosol generation device reduces the risk of mildew and corrosion inside the aerosol generation device, thus increasing the durability of the aerosol generation device. An additional benefit of an aerosol generation device that is airtight is that under low pressure conditions, the amount of air inside the device that can expand is minimized, and the risk of damage to the aerosol generation device due to air inside the aerosol generation device expanding is reduced.

According to a 36^{th} aspect, in any one of the preceding aspects, the aerosol generation device comprises one or more sealing elements that seal a housing of the aerosol generation device at ingress points or seams of the housing, such that the aerosol generation device is airtight.

The 36^{th} aspect is advantageous because an airtight device is protected against ingress of dust, water and other particulates that may cause damage to the aerosol generation device. This improves the durability and reliability of the aerosol generation device.

According to a 37^{th} aspect, in any one of the preceding aspects, when not arranged in the aerosol generation device, the first FPC can be arranged in substantially the same plane as the first rigid PCB by bringing the first FPC into a substantially planar shape to form a substantially planar aggregate shape, wherein the first rigid PCB and the first FPC overlap only at portions where the first FPC is connected and/or attached to the first rigid PCB.

According to a 38^{th} aspect, in the preceding aspect and the 2^{nd} aspect, the second FPC can be arranged in substantially the same plane as the first rigid PCB by bringing the second FPC into a substantially planar shape to form a substantially planar aggregate shape with the first rigid PCB and the first FPC, wherein the first rigid PCB, the first FPC and the second FPC overlap only at portions where the first FPC and the second FPC are respectively connected and/or attached to the first rigid PCB.

According to a 39^{th} aspect, in the preceding aspect and the 16^{th} aspect, the second rigid PCB, or the third FPC and the second rigid PCB, can be arranged in substantially the same plane as the first rigid PCB by bringing the first FPC with the third portion or the second FPC with the third portion, or by bringing the third FPC into a substantially planar shape, to form a substantially planar aggregate shape with the first rigid PCB and the first FPC and the second FPC, or with the first rigid PCB and the first FPC and the second FPC and the third FPC, wherein the first rigid PCB and the second rigid PCB and the first FPC and the second FPC, or the first rigid PCB and the second rigid PCB and the first FPC and the second FPC and the third FPC overlap only at portions where the first FPC and the second FPC, or the first FPC and the second FPC and the third FPC are respectively connected and attached to the first rigid PCB and/or the second rigid PCB.

The 37th, 38th, and 39^{st} aspects are advantageous because they allow the first FPC, or the first FPC and the second FPC, or the first FPC and the second FPC and the third FPC to be manufactured and cut-out from a single printed circuit board profile. This reduces material waste during manufacture.

According to a 40^{th} aspect, in any one of 37^{th} to 39^{th} aspects and the 14^{th} aspect, the length of the aggregate shape is the maximum extensions of the aggregate shape in the longitudinal direction of the aerosol generation device, and the width of the aggregate shape is the maximum extensions of the aggregate shape in the transverse direction of the aerosol generation device in the plane of the first rigid PCB, and the ratio between (i) the total area of the aggregate shape, and (ii) the total area of a rectangle (R) that has the length and width of the aggregate shape is larger than 30%, preferably larger than 40%, more preferably larger than 50%, more preferably larger than 60%, more preferably larger than 70%, even more preferably larger 80%, most preferably larger than 90%.

The 40^{th} aspect is advantageous because it reduces material waste during manufacture of the first FPC, or the first FPC and the second FPC, or the first FPC and the second FPC and the third FPC, because the FPCs can be cut out from a single printed circuit board profile with reduced areas of the board profile being unoccupied and consequently wasted.

### BRIEF DESCRIPTION OF THE DRAWINGS

FIG. 1 shows a schematic illustration of a side view of an aerosol generation device according to embodiments of the invention;

FIGS. 2A and 2B show illustrations of a schematic view, from the directions respectively indicated by the arrows marked A and B in FIG. 1, of circuitry of an aerosol generation device according to embodiments of the invention;

FIGS. 3A and 3B show illustrations of a schematic view, from the direction indicated by the arrow marked A in FIG. 1, of circuitry of an aerosol generation device according to embodiments of the invention;

FIGS. 4A, 4B, and 4C show illustrations of different schematic side views of circuitry of an aerosol generation device according to embodiments of the invention;

FIG. 5A shows a schematic illustration of a top view of circuitry in a planar shape of an aerosol generation device according to the prior art, and FIGS. 5B and 5C show schematic illustration of a top view of circuitry of an aerosol generation brought to a planar shape, according to embodiments of the invention.

### DETAILED DESCRIPTION OF PREFERRED EMBODIMENTS

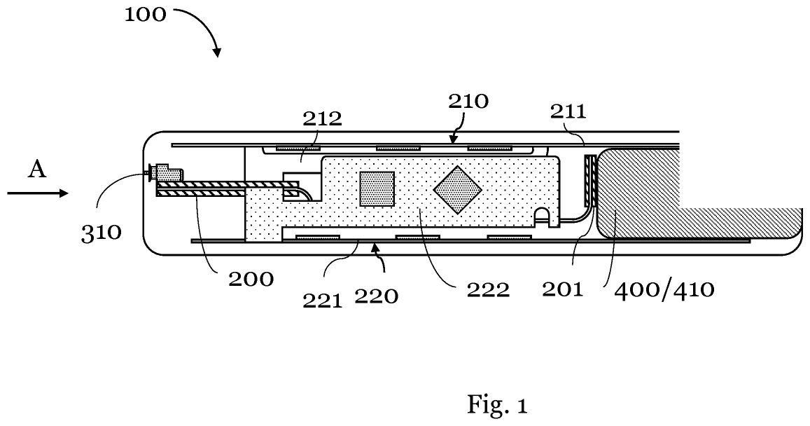

As shown in FIG. 1, an aerosol generation device 100 comprises circuitry for controlling the operation of the aerosol generation device 100. The circuitry comprises a first rigid printed circuit board (PCB) 200 that may be arranged such that it extends in a longitudinal direction of the aerosol generation device 100 that extends from a first end of the aerosol generation device 100 to a second end of the aerosol generation device 100 opposite the first end. At or proximate a first end, the aerosol generation device 100 may be provided with an aerosol generation means 400. The aerosol generation means 400 may be configured to generate an aerosol with a cartomizer 410. The aerosol generation means 400 may thus comprise means for receiving and electrically interfacing with the cartomizer, such as, e.g., one or more pogo pins, magnetic elements or similar interfacing elements. Alternatively, the aerosol generation means 400 may be configured to generate an aerosol from an attachable/removeable cartridge containing an aerosol generation substrate such as an e-liquid or t-liquid. The aerosol generation means 400 may thus comprise a wicking element that wicks liquid contained in the cartridge, and a heating element that heats liquid in the wicking element. Alternatively, the aerosol generation means comprises a refillable liquid reservoir that is in communication with a wicking element and a heating element for heating liquid in the wicking element. Alternatively, the aerosol generation means 400 may be configured for generating an aerosol from a tobacco stick. The aerosol generation means 400 may thus comprise a receptable for receiving a tobacco stick, and a heating element for heating the receptacle and the received tobacco stick.

The aerosol generation device 100 is provided with a power supply 300. The power supply 300 may be a rechargeable power supply and/or a replaceable power supply such as a battery. In case of a rechargeable power supply 300, the aerosol generation device may be provided with a charging interface 310 that may be provided at or proximate a second end of the aerosol generation device 100 opposite the first end at or proximate to which an aerosol generation means 400 may be provided. The charging interface may be a charging port such as a USB port or similar port. In case of a replaceable power supply, instead of a charging interface 310, the aerosol generation device wo may be provided with a releasable cap or sealable opening or a similar arrangement that is configured to allow the power supply 300 to be replaced.

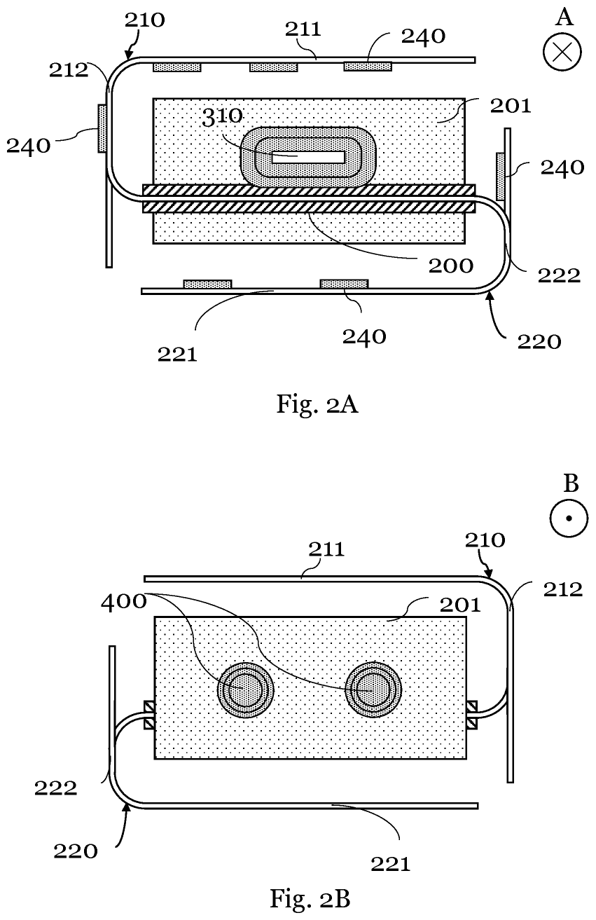

The aerosol generation device 100 is provided with circuitry to which to the power supply 300, the charging interface 310, and/or the aerosol generation means 400 are connected and/or attached. The circuitry comprises a first rigid PCB 200 and a first FPC 210, and may further comprise a second FPC 220 and optionally a third FPC 230. The circuitry may further comprise a second rigid PCB 201. The circuitry will be described in detail in embodiments as described below in the context FIGS. 2A through 5C.

As shown in FIG. 2A, the first rigid PCB 200 may extend in the longitudinal direction of the aerosol generation device 100. A first FPC 210 comprises a first portion 211 that is arranged to be substantially parallel to the first rigid PCB 200 and is connected to the first rigid PCB 200 by a second portion 212. A second FPC 220 may be provided that comprises a first portion 221 that is arranged to be substantially parallel to the first rigid PCB 200 and that is connected to the first rigid PCB 200 by a second portion 222. The first FPC 210 and the second FPC 220 as shown may preferably be formed by a single integrally formed FPC. The single FPC may be attached to the first rigid PCB 200 by being interposed between two separate layers of the first rigid PCB 200. Such a configuration eliminates the need for the first FPC 210 and the second FPC 220 to be connected and attached to the first rigid PCB 200 by one or more connector means. Alternatively, the single FPC may be attached only to one layer of the first rigid PCB with a portion of a first surface of the single FPC, and remain uncovered by the first rigid PCB 200 on a second surface of the single FPC opposite the first surface. The first FPC 210 may be provided with one or more electronic and/or electrical components 240 on one or both surfaces of the first FPC 210, and the second FPC 220 as well may be provided with one or more electronic and/or electrical components 240 on one or both surfaces of the second FPC 220. The first FPC 210 and the first rigid PCB 200 may form a first bent or curved shape that allows the first FPC 210 to adapt and conform to differently shaped inner surfaces of the interior space of the aerosol generation device 100. Analogously, the second FPC 220 and the first rigid PCB 200 may form a second bent or curved shape that allows the second FPC 220 to adapt and conform to differently shaped inner surfaces of the interior space of the aerosol generation device 100. Preferably, the first portion 211 of the first FPC 211, and the first portion 221 of the second FPC 220 are arranged to face opposite surfaces of the first rigid PCB 200. As a result, the first portion 211 and the second portion 212 of the first FPC 210, the first rigid PCB 200, and the first portion 221 and the second portion 222 of the second FPC 220 form a substantially “S”-letter shaped shape in a transversal plane of the aerosol generation device 100 that is parallel to the viewing plane of FIG. 2A. This arrangement increases the surface area that can be provided with electronic and/or electrical components within the interior space of the aerosol generation device 100.

A charging port 310 may be provided on and/or connected and/or attached to the first rigid PCB 200. The first rigid PCB 200 provides a stable mechanical support for the charging port that is subjected to physical wear and tear due to a corresponding charging connector being connected and disconnected to and from the charging port over the lifetime of the aerosol generation device.

As shown in FIG. 2B, a second rigid PCB 201 may be provided. The second rigid PCB 201 may be connected and attached to the first rigid PCB 200 by a third portion 213 of the first FPC 210, or by a third portion 223 of the second FPC 220, or by a third FPC 230. The third FPC 230 may be a separate FPC or be part of a single integrally formed FPC that includes the first FPC 210 and the second FPC 220. The second rigid PCB 201 may be arranged to be in a transverse plane of the aerosol generation device 100 and thus substantially perpendicular to the first rigid PCB 200. As shown, the second rigid PCB 201 may be provided with interfacing and receiving means such as a pogo pin for receiving and electrically interfacing with a cartomizer 410 that may be used with the aerosol generation device 100. Alternatively, the aerosol generation device 100 may be provided with different aerosol generation means as described for embodiments in the context of FIG. 1. The second rigid PCB 201 may be connected to the respective aerosol generation means. Depending on the orientation and/or type of the connecting or interfacing means of the aerosol generation means, the second rigid PCB 201 may also be arranged to be substantially parallel to the first rigid PCB 200.

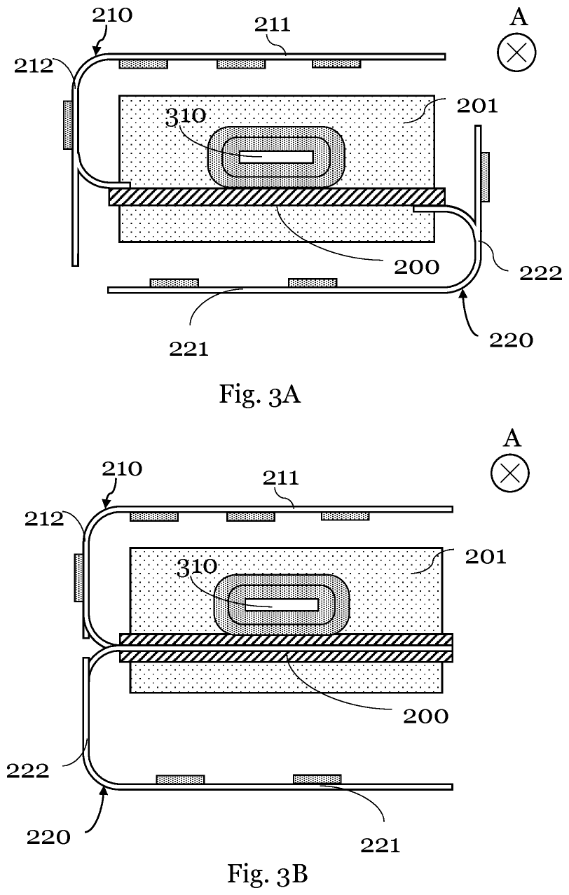

FIGS. 3A and 3B show modifications of the circuitry of an aerosol generation device that may be an aerosol generation device as described for embodiments in the context of FIGS. 1 through 2B. As shown in FIG. 3A, the upper half of an “S”-letter shaped shape in a transversal plane or a similar curved or bent shape of the aerosol generation device wo may be formed by a first FPC 210 and the first rigid PCB 200. Additionally, a second FPC 220 may be provided that, together with the first rigid PCB 200, forms the lower half of the “S”-letter shaped shape or a similar curved or bent shape. Instead of a single integrally formed FPC, the first FPC 210 and the second FPC 220 may be separate FPCs that are each connected and/or attached to the first rigid PCB 200 via respective connector means (not shown). While the first FPC 210 and the second FPC 220 are shown to be connected and attached to the first rigid PCB 200 on opposing surfaces of the first rigid PCB 200, they each may be connected and attached to the first rigid PCB 200 on the same surface. As shown in FIG. 3B, as another modification to the circuitry of an aerosol generation device 100 that may be an aerosol generation device wo as described for embodiments in the context of FIGS. 1 through 2B, instead of forming a substantially “S”-letter shaped shape, the first portion 211 and the second portion 212 of the first FPC 210, the first rigid PCB 200, and the first portion 212 and the second portion 220 of the second FPC may form an “E”-letter shaped shape in a transverse plane of the aerosol generation device 100.

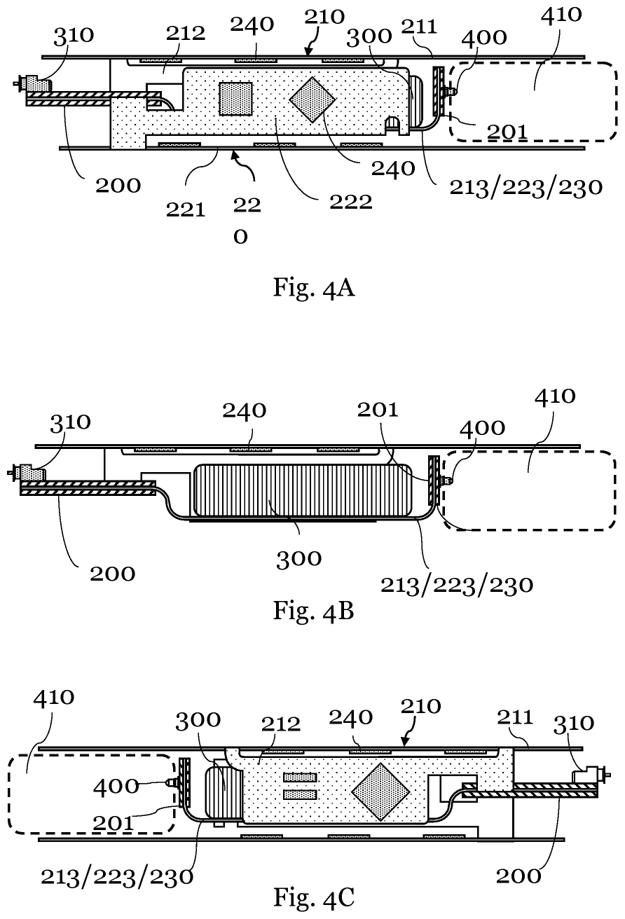

FIGS. 4A, 4B and 4C show different side views of an aerosol generation device 100 that may be an aerosol generation device as described for embodiments in the context of FIGS. 1 through 3B. As shown, a second rigid PCB 201 may be provided and arranged to be in a transverse plane of the aerosol generation device wo and perpendicular to the first rigid PCB 200. Depending on the configuration, the second rigid PCB 201 may be connected and attached to the first rigid PCB 200 via a third FPC 230. Alternatively, the second rigid PCB 201 may be connected to the first rigid PCB 200 via a third portion 213 of the first FPC 210, or via a third portion 223 of the second FPC 220. At least a portion of the third FPC 230 extends in the longitudinal direction of the aerosol generation device 100. The third FPC 230 may have a bent or curved shape in a longitudinal plane of the aerosol generation device 100. A power supply 300 that may be a power supply 300 as described for embodiments in the context of FIG. 1 may be provided on the third FPC 230. The first FPC 210 and/or the second FPC 220 and/or the third FPC 230 are configured to wrap around at least a portion of the power supply 300. In particular, in a transverse plane of the aerosol generation device 100, at least a portion or all of the power supply 300 may be arranged between the first portion 211 of the first FPC 210 and the first rigid PCB 200, or between the first portion 221 of the second FPC 220 and the first rigid PCB 200, or between the first portion 211 of the first FPC 210 and the first portion 221 of the second FPC 220. This allows the circuitry of the aerosol generation device wo to make use of a section extending in the longitudinal direction of the interior space of the aerosol generation device 100 in which the power supply 300 is arranged and that would otherwise not be suitable for accommodating electronic and/or electrical components.

While the first rigid PCB is shown to be provided with a charging interface 310 and the second rigid PCB is shown to be provided with pogo pins 400 for receiving and interfacing with a cartomizer 410, alternatively, the arrangement may also be reversed, i.e. the first rigid PCB 200 is provided with the pogo pins 400, and the second rigid PCB 201 is provided with the charging interface 310. Alternatively, the second rigid PCB 201 may also be omitted, and the pogo pins 400 or other interfacing means may be provided on the third FPC. Alternatively, the second rigid PCB 201 may be arranged substantially parallel to the first FPC 210.

A portion of the first FPC 210 that may be the first portion 211 of the first FPC 210 and a portion of the second FPC 220 that may be the first portion 221 of the second FPC 220 may preferably extend in the longitudinal direction of the aerosol generation device 100. Preferably, the extension of the first FPC (210) and/or the second FPC 220 in the longitudinal direction of the aerosol generation device 100 is larger than 50%, preferably larger than 60%, more preferably larger than 70%, even more preferably larger than 80%, most preferably larger than 90% of the longitudinal extension of the aerosol generation device 100. This allows an increased amount of the interior space of the aerosol generation device wo to be utilized and thus leads to a more efficient use of the interior space of the aerosol generation device 100. Additionally, the first portion 211 of the first FPC 210 and/or the first portion 211 of the second FPC 220 may extend, in the longitudinal direction of the aerosol generation device 100, further away from the first rigid PCB 200 than the second rigid PCB 201, and thus extend along at least a portion of the heating chamber or cartomizer 410 when received by the aerosol generation device 100, as shown in FIGS. 1, 4A, 4B and 4C. Preferably, at least 10%, preferably more than 20%, more preferably more than 30%, even more preferably more than 40%, most preferably more than 50% of the extension of the first FPC 210 and/or the second FPC 220 in the longitudinal direction of the aerosol generation device extends along at least a portion the heating chamber or cartomizer when in use. This also allows electronic or electrical components providing functionalities to the aerosol generation device to be accommodated at positions proximate the heating chamber or the cartomizer 410 that normally would not be suitable for accommodating components of the aerosol generation device 100.

An aerosol generation device 100 as described for any one of the embodiments of the present invention may be an airtight aerosol generation device 100. An airtight aerosol generation device 100 may prevent ingress of dust, dirt or liquids into the aerosol generation device 100 by being provided with one or more airtight sealing elements at ingress points or seams of the outer housing 101 of the aerosol generation device. In particular, ingress of liquids can cause damage to non-airtight devices as commonly used e-liquid or t-liquid substrates can leak or spill. It should be noted that the increased surface area of the circuitry of an aerosol generation device as described for embodiments of the invention provides a more efficient use of the interior space of the aerosol generation device that may on the one hand be utilized for providing the aerosol generation device 100 with more and/or improved functionalities. In case of an airtight aerosol generation device, it may be preferable to utilize the more efficient use of interior space inside the aerosol generation device 100 to render the aerosol generation device more compact. This can be achieved by reducing the volume of unoccupied space inside the aerosol generation device 100. Unoccupied space refers to any space contained inside a boundary defined by the outer housing 101 of the aerosol generation device 100 that is not occupied by functional or structural components of the aerosol generation device 100. While reducing the unoccupied space inside an aerosol generation device 100 in general is advantageous because it reduces the risk of mildew and corrosive effects taking place, reducing and minimizing unoccupied space inside an airtight aerosol generation device 100 has the added benefit that the device is less susceptible to being damaged under low-pressure conditions that may commonly occur on airplanes. By reducing the unoccupied space inside the aerosol generation device 100, the amount of air contained in the unoccupied space that can expand is reduced, and thus the risk of the expansion of air damaging the aerosol generation device is reduced. Preferably, the volume of the unoccupied space inside the aerosol generation device 100 is less than 40%, preferably less than 30%, even more preferably less than 20%, most preferably less than 10% of the interior volume of the aerosol generation device (100) that is defined by the housing 101 of the aerosol generation device 100 as the outer boundary.

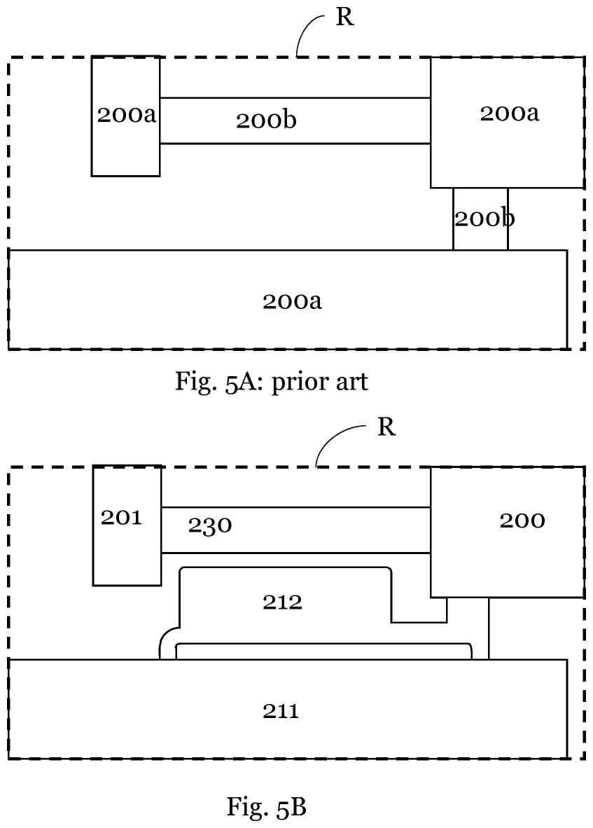

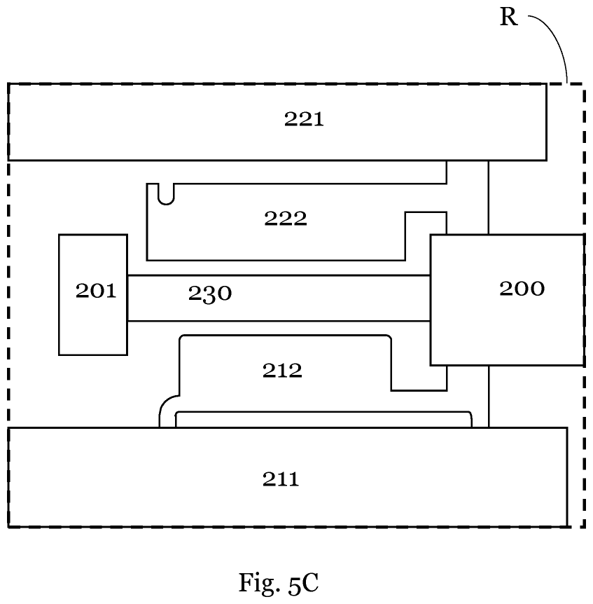

In addition to improving the efficient use of the interior space of an aerosol generation device wo by increasing the surface area for providing more functionalities to an aerosol generation device 100, or for rendering the aerosol generation device wo more compact, embodiments of the present invention also contribute to a more efficient use of raw materials or precursor materials from which circuitry as described for embodiments of the invention can be manufactured. FIG. 5A shows circuitry of an aerosol generation device according to the prior art, the circuitry being in a planar shape. The shown circuitry comprises component circuit elements 200a that are connected to each other via connection circuit elements 200b. The component circuit elements 200a may be rigid PCBs, and the connection circuit element 200b may be FPCs. Alternatively, the circuitry may be a flexi-rigid circuit. Thus, the connection circuit components 200b may be formed by a single integrally formed PFC that is attached to the component circuit elements 200a. In any case, the connection circuit elements 200b are commonly only designated for connecting different component circuit elements 200a. When manufacturing the FPCs or the single integrally formed FPC, at least a portion of the area of the component circuit elements 200a and the areas of the connection circuit elements 200b are cut out from a rectangular FPC board profile marked as R in FIG. 5A, while the remaining area is cut-off and consequently wasted.

In comparison, FIG. 5B shows circuitry of an aerosol generation that may be an aerosol generation device as described for embodiments in the context of FIGS. 2A through 3B. The shown circuitry comprises a first rigid PCB 200, a first rigid FPC 210, a third FPC 230 and a second rigid PCB 201. The first rigid FPC 210 and the third FPC 230 may be separate FPCs that are connected to the first rigid PCB 200 and/or the second rigid PCB 201. Alternatively, the first FPC 210 and the third FPC 230 may be formed by a single integrally formed FPC. The first rigid PCB 200, the second rigid PCB 201, the first rigid FPC 210 and the third FPC 230 can be arranged to form a substantially planar aggregate shape by bringing the first FPC 210 and the third FPC 23o, or by bringing the single integrally formed FPC into a planar shape. The planar aggregate shape is shown in FIG. 5B. In the planar aggregate shape, the first rigid PCB 200, the second PCB 201, the first FPC, and the third FPC 230 overlap only in portions where the first FPC 210 and the third FPC 230, or in portions where the single integrally formed FPC are respectively connected and/or attached to the first PCB 200 and/or the second rigid PCB 201S. When manufacturing the first FPC 210 and the second FPC 220, or when manufacturing the single FPC, at least a portion or all of the area of the first rigid PCB 200 and the second rigid PCB 201, and the areas of the first FPC 210 and the third FPC 230 will be cut-out from an FPC board profile marked as R. As clearly evident, in contrast to the prior art, at least the areas of the second portion 212 of the first FPC 210 are not wasted.

Similarly, FIG. 5C shows circuitry of an aerosol generation device that is an aerosol generation device as described in the context of FIG. 2A. The shown circuitry comprises a first rigid PCB 200, a first rigid FPC 210, a second FPC 220, a third FPC 230 and a second rigid PCB 201. The first rigid FPC 210, the second FPC 220 and the third FPC 230 may be formed by a single integrally formed FPC. The first rigid PCB 200, the second rigid PCB 201, the first FPC 210, the second FPC 220, and the third FPC 230 can be arranged to form a substantially planar aggregate shape by bringing the first FPC 210, the second FPC 220, and the third FPC 230 into a planar shape. The planar aggregate shape is shown in FIG. 5C. In the planar aggregate shape, the first rigid PCB 200, the second PCB 201, the first FPC, the second FPC 220, and the third FPC 230 overlap only in portions where the first FPC 210, the second FPC 200, and the third FPC 230 are respectively connected and/or attached to the first PCB 200 and/or the second PCB 201. When manufacturing the first FPC 210, the second FPC 220, and the third FPC 230, or when manufacturing the single integrally formed FPC, at least a portion or all of the area of the first rigid PCB 200 and the second rigid PCB 201, as well as the areas of the first FPC 210, the second FPC 220, and the third FPC 230 will be cut-out from an FPC board profile marked as R. As clearly evident, in contrast to the prior art, the areas of the second portion 212 of the first FPC 210 and the second portion 222 of the second FPC 220 are not wasted compared to the prior art.

Ideally, the percentage of the area of the board profile R that is cut-out for a circuitry of the aerosol generation device wo should be as high as possible to minimize waste of material. Depending on the configuration of the circuitry, the ratio between
(i) the total area of the aggregate shape, and
(ii) the total area of a rectangular board profile (R) is larger than 30%, preferably larger than 40%, more preferably larger than 50%, more preferably larger than 60%, more preferably larger than 70%, even more preferably larger 80%, most preferably larger than 90%.

It should be noted that a flexible printed circuit (FPC) as described for all embodiments of the invention may comprise a single-sided flex circuit, a back-bared flex circuit and a double-sided flex circuit. The flexible printed circuit typically comprises a material that comprises or substantially consists of polyamide.

It should further be noted that a substantially parallel arrangement of two planes or planar shapes allows a plus-minus 5 degrees tilt angle between substantially parallel planes. Within the geometric dimensions typical for aerosol generation devices, such a tilt is inconsequential.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the scope of this disclosure, as defined by the independent and dependent aspects.

### LIST OF REFERENCE SIGNS USED

100: aerosol generation device
101: aerosol generation device housing
200: circuitry
200a: prior art: component circuit element
200b prior art: connection circuit element
201: first rigid PCB
210: first FPC
211: first portion of first FPC
212: second portion of first FPC
213: third portion of first FPC
220: second FPC
221: first portion of second FPC
222: second portion of second FPC
223: third portion of second FPC
230: third FPC
240: electronic and/or electrical components
300: power supply
400: aerosol generation means
410: cartomizer

1. An aerosol generation device comprising:
a first rigid printed circuit board (PCB) arranged in a first plane; and
a first flexible printed circuit (FPC); wherein
the first rigid PCB is attached to a first portion of the first FPC,
the first portion of the first FPC is arranged in a second plane that is substantially parallel to and different from the first plane, and
a second portion of the first FPC connects the first portion of the first FPC to the first rigid PCB.

2. The aerosol generation device according to claim 1, comprising:
a second FPC; wherein
the first rigid PCB is attached to a portion of the second FPC,
a first portion of the second FPC is arranged in a third plane that is substantially parallel to and different from the first plane and the second plane, and
a second portion of the second FPC connects the first portion of the second FPC portion to the first rigid PCB.

3. The aerosol generation device according to claim 2, wherein the second plane faces a first surface of the first rigid PCB and the third plane faces a second surface of the first rigid PCB that is opposite the first surface of the first rigid PCB;
wherein at least part of the first portion of the first FPC faces the first surface of the first rigid PCB, and/or
wherein at least part of the first portion of the second FPC faces the second surface of the first rigid PCB.

4. The aerosol generation device according to claim 1, wherein the first rigid PCB, the first portion of the first FPC, and the second portion of the first FPC form a first curved or bent shape in a transversal plane of the aerosol generation device.

5. The aerosol generation device according to claim 4, wherein the first rigid PCB, the first portion of the second FPC), and the second portion of the second FPC form a second curved or bent shape in a transversal plane of the aerosol generation device.

6. The aerosol generation device according to claim 5, wherein the first curved or bent shape and the second curved or bent shape are curved or bent in a same direction.

7. The aerosol generation device according to claim 6,
wherein the first curved or bent shape and the second curved or bent shape together form a substantially “E”-letter shaped shape in a transversal plane of the aerosol generation device

8. The aerosol generation device according to claim 2, wherein the first rigid PCB has or comprises an elongated shape, and at least a portion of the first FPC and the second FPC extends in a direction that is parallel to a longitudinal axis of the first rigid PCB.

9. The aerosol generation device according to claim 8, comprising a second rigid PCB that is connected to a third portion of the first FPC, or a third portion of the second FPC, or a third FPC of which a portion is attached to the first rigid PCB, wherein the second rigid PCB is arranged in a plane that is parallel to a transverse plane of the first rigid PCB.

10. The aerosol generation device according to claim 9, wherein the first FPC and the second FPC and the third FPC are formed by a single, integrally formed FPC.

11. The aerosol generation device according to claim 1, further comprising an aerosol generation means for receiving and/or interfacing with a consumable comprising an aerosol generation substrate for generating an aerosol from the aerosol generation substrate,
wherein the aerosol generation means is provided substantially at a first end of the aerosol generation device.

12. The aerosol generation device according to claim 1, further comprising a power supply,
wherein at least a portion of the first FPC wraps around at least a portion of the power supply and, in a transversal plane of the aerosol generation device, at least a portion or all of the of the power supply is arranged between the first portion of the first FPC and the first rigid PCB.

13. The aerosol generation device according to claim 1, wherein less than 40% of an interior volume of the aerosol generation device that is defined by a housing of the aerosol generation device as an outer boundary is unoccupied and can be filled with air.

14. The aerosol generation device according to claim 1, wherein, when not arranged in the aerosol generation device, the first FPC is arranged in substantially the same plane as the first rigid PCB with the first FPC in a substantially planar shape to form a substantially planar aggregate shape, wherein
the first rigid PCB and the first FPC overlap only at portions where the first FPC is connected and/or attached to the first rigid PCB.

15. The aerosol generation device according to claim 2, wherein, when not arranged in the aerosol generation device, the first FPC is arranged in substantially the same plane as the first rigid PCB with the first FPC in a substantially planar shape to form a substantially planar aggregate shape, wherein
the first rigid PCB and the first FPC overlap only at portions where the first FPC is connected and/or attached to the first rigid PCB, wherein
the second FPC is arranged in substantially the same plane as the first rigid PCB with the second FPC into a substantially planar shape to form a substantially planar aggregate shape with the first rigid PCB and the first FPC, and wherein
the first rigid PCB and the first FPC and the second FPC overlap only at portions where the first FPC and the second FPC are respectively connected and/or attached to the first rigid PCB.

16. The aerosol generation device according to claim 9, wherein, when not arranged in the aerosol generation device, the first FPC is arranged in substantially the same plane as the first rigid PCB with the first FPC in a substantially planar shape to form a substantially planar aggregate shape, wherein
the first rigid PCB and the first FPC overlap only at portions where the first FPC is connected and/or attached to the first rigid PCB, wherein
the second FPC is arranged in substantially the same plane as the first rigid PCB with the second FPC in a substantially planar shape to form a substantially planar aggregate shape with the first rigid PCB and the first FPC, and wherein
the first rigid PCB and the first FPC and the second FPC overlap only at portions where the first FPC and the second FPC are respectively connected and/or attached to the first rigid PCB, wherein
the second rigid PCB, or the third FPC and the second rigid PCB is arranged in substantially the same plane as the first rigid PCB with the first FPC with the third portion or the second FPC with the third portion, or with the third FPC in a substantially planar shape, to form a substantially planar aggregate shape with the first rigid PCB and the first FPC and the second FPC, or with the first rigid PCB and the first FPC and the second FPC and the third FPC, wherein
the first rigid PCB and the second rigid PCB and the first FPC and the second FPC, or the first rigid PCB and the second rigid PCB and the first FPC and the second FPC and the third FPC, overlap only at portions where the first FPC and the second FPC, or at portions where the first FPC and the second FPC and the third FPC are respectively connected and/or attached to the first rigid PCB and/or the second rigid PCB.

17. The aerosol generation device according to claim 8, wherein, when not arranged in the aerosol generation device, the first FPC is arranged in substantially the same plane as the first rigid PCB with the first FPC in a substantially planar shape to form a substantially planar aggregate shape, wherein
the first rigid PCB and the first FPC overlap only at portions where the first FPC is connected and/or attached to the first rigid PCB,
wherein a length of the aggregate shape is a maximum extension of the aggregate shape in a longitudinal direction of the aerosol generation device, and
a width of the aggregate shape is a maximum extension of the aggregate shape in a transverse direction of the aerosol generation device in the first plane of the first rigid PCB,
wherein a ratio between
(i) a total area of the aggregate shape, and
(ii) a total area of a rectangle that has the length and the width of the aggregate shape
is larger than 30%.

18. The aerosol generation device according to claim 5, wherein the first curved or bent shape and the second curved or bent shape are curved or bent in opposite directions.

19. The aerosol generation device according to claim 18,
wherein the first curved or bent shape and the second curved or bent shape together form a substantially “S”-letter shaped shape in a transversal plane of the aerosol generation device.

20. The aerosol generation device according to claim 8, wherein, when not arranged in the aerosol generation device, the first FPC is arranged in substantially the same plane as the first rigid PCB with the first FPC in a substantially planar shape to form a substantially planar aggregate shape, wherein
the first rigid PCB and the first FPC overlap only at portions where the first FPC is connected and/or attached to the first rigid PCB,
wherein a length of the aggregate shape is a maximum extension of the aggregate shape in a longitudinal direction of the aerosol generation device, and
a width of the aggregate shape is a maximum extension of the aggregate shape in a transverse direction of the aerosol generation device in the first plane of the first rigid PCB,
wherein a ratio between
(i) a total area of the aggregate shape, and
(ii) a total area of a rectangle that has the length and the width of the aggregate shape
is larger than 90%.
